(19) United States
(12) Patent Application Publication
(10) Pub. No.: US 2003/0160229 A1
(43) Pub. Date: Aug. 28, 2003

(54) Efficient light emitting diodes and lasers

(75) Inventors: Jagdish Narayan, Raleigh, NC (US); Jinlin Ye, South Easton, MA (US); Schang-Jing Hon, Attleboro, MA (US); Ken Fox, Clinton, MA (US); Jyh Chia Chen, Ellicott City, MD (US); Hong K. Choi, Sharon, MA (US); John C. C. Fan, Brookline, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Kopin Corporation, Taunton, MA

(21) Appl. No.: 10/083,703

(22) Filed: Feb. 25, 2002

(51) Int. Cl. H01L 29/06; H01L 31/0328; H01L 31/0336; H01L 31/0232

(52) U.S. Cl. 257/14; 257/82; 257/103; 257/291; 257/432; 438/35; 438/46

(57) ABSTRACT

An optoelectronic device such as an LED or laser which produces spontaneous emission by recombination of carriers (electrons and holes) trapped in Quantum Confinement Regions formed by transverse thickness variations in Quantum Well layers of group III nitrides.

### BACKGROUND OF THE INVENTION

Light emitting diodes (“LEDs”) are p-n junction devices that have been found to be useful in various roles as the field of optoelectronics has grown and expanded over the years. Devices that emit in the visible portion of the electromagnetic spectrum have been used as simple status indicators, dynamic power level bar graphs, and alphanumeric displays in many applications, such as audio systems, automobiles, household electronics, and computer systems, among many others. Infrared devices have been used in conjunction with spectrally matched phototransistors in optoisolators, hand-held remote controllers, and interruptive, reflective, and fiber-optic sensing applications.

An LED operates based on the recombination of carriers (electrons and holes) in a semiconductor. When an electron in the conduction band combines with a hole in the valence band, it loses energy equal to the bandgap of the semiconductor in the form of an emitted photon; i.e., light. The number of recombination events under equilibrium conditions is insufficient for practical applications but can be enhanced by increasing the minority carrier density.

The minority carrier density is conventionally increased by forward biasing the diode. The injected minority carriers recombine with the majority carriers within a few diffusion lengths of the junction edge, generating photons at a wavelength corresponding to the bandgap energy of the semiconductor.

As with other electronic devices, there exists both the desire and need for more efficient LEDs, and in particular, LEDs that will operate at higher intensity while using less power. Higher intensity LEDs, for example, are particularly useful for displays or status indicators in various high ambient environments. High efficiency LEDs with lower power consumption, for example, are particularly useful in various portable electronic equipment applications. An example of an attempt to meet this need for higher intensity, lower power, and more efficient LEDs may be seen with the development of the AlGaAs LED technology for the red portions of the visible spectrum. A similar continual need has been felt for LEDs that will emit in the green, blue and ultraviolet regions of the visible spectrum which ranges from 400 nanometers (nm) (3.10 eV) to 770 nm (1.61 ev). Because red, green, and blue are primary colors, their presence is necessary to produce full color displays or pure white light.

As mentioned above, the wavelength ( [symbol] ) of photons that can be produced by a given semiconductor material is a function of the material's bandgap (E_{g}). This relationship can be expressed as [symbol] (nm)=1240/E_{g}(eV). Thus smaller bandgap materials produce lower energy, longer wavelength photons, while wider bandgap materials are required to produce higher energy, shorter wavelength photons. For example, one semiconductor commonly used for lasers is indium gallium aluminum phosphide (InGaAlP). This material's bandgap depends upon the mole or atomic fraction of each element present, and the light that InGaAlP can produce is limited to the yellow to red portion of the visible spectrum, i.e., about 560 to 700 nm.

In order to produce photons that have wavelengths in the green, blue or ultraviolet (UV) portions of the spectrum, semiconductor materials with relatively large bandgaps are required. Typical candidate materials include silicon carbide (6H-SiC with a bandgap of 2.5 eV) and alloys of indium nitride (InN with a bandgap of 1.9 eV), gallium nitride (GaN with a bandgap of 3.4 eV) and aluminum nitride (AlN with a bandgap of 6.2 eV). Since these nitrides can form solid solutions, the bandgap of these alloys (AlInGaN) can be tuned potentially from 1.9 eV to 6.2 eV with a corresponding wavelength varying from 653 nm to 200 nm at room temperature.

### SUMMARY OF THE INVENTION

Aluminum indium gallium nitride (AlInGaN) is a very attractive LED candidate material for green, blue and UV wavelengths because of its relatively large bandgap at room temperature and because it is a direct bandgap material rather than an indirect bandgap material. Generally speaking, an LED formed in a direct bandgap material is more efficient than one formed in an indirect bandgap material because the recombination of carriers occurs directly without the help of phonons (lattice vibration) and the photon from the direct transition retains more energy than one from an indirect transition.

Because the bulk gallium nitride (hexagonal GaN; a=0.3189 nm, c=0.5185 nm) substrates are not readily available, AlInGaN layers are typically grown on a sapphire (hexagonal alpha-Al₂O₃; a=0.4578 nm, c=1.299 nm) or on a silicon carbide substrate (hexagonal 6H-SiC; a=0.308 nm, c=1.512 nm). The AlInGaN films grow by lattice matching epitaxy on 6H-SiC, and by domain matching epitaxy on sapphire. The AlInGaN growth on sapphire involves a 30/90 degree rotation in the basal plane, and 6/7 domain matching of the major planes between the film and the substrate. The differences in lattice constants and coefficients of thermal expansion between the film and the substrate cause misfit strains which result in high dislocation densities in AlInGaN layers, typically around 10¹⁰ cm⁻². When carriers (electrons and holes) are trapped by dislocations, they recombine non-radiatively without generating light.

In accordance with a first embodiment of the invention, an efficient opto electronic device of the type which produces spontaneous emission by radiative recombination of carriers (electrons and holes) is formed of a layered quantum well (QW) structure in which the thickness of the QW layers varies periodically. It is believed that the thickness variations result in the formation of Quantum Confinement (QC) regions, which trap the carriers. If the QC regions are smaller than the separation between dislocations, the trapped carriers recombine radiatively and efficiently produce photons. In another embodiment, Al is added to InGaN to increase the wavelength to produce a Al_{y}InₓGa_{(1-x-y)}N Laser Device (LD) or multiquantum well (MQW) LED.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic of Short-Range Thickness Variation (SR-TV) and Long-Range Thickness Variation (LR-TV) of a portion of the active GaN/InGaN quantum well superlatice layers in a high efficiency light emitting diode structure.

FIG. 2 is a schematic of showing details of the LED structure.

FIG. 3A is a scanning transmission electron microscopy-atomic number (STEM-Z) contrast image in cross-section showing short-range thickness variation in the active InGaN layer in a high efficiency LED structure.

FIG. 3B is a enlargement of FIG. 3A.

FIG. 4 is a STEM-Z contrast image in cross-section showing long-range thickness variation in all ten InGaN layers of a multiple-quantum-well (MQW) structure.

FIG. 5A is a STEM-Z contrast image of cross-section showing characteristic long-range thickness variation in a InGaN/GaN MQW structure from another high-efficiency LED wafer.

FIG. 5B is a STEM-Z contrast image of the cross-section showing the short-range thickness variation in a InGaN/GaN MQW structure (same wafer as FIG. 5A).

FIG. 6A is a STEM-Z contrast image showing uniform InGaN layers in a relative low efficiency LED structure.

FIG. 6B is a enlargement if FIG. 6A.

FIG. 7 is a comparison of output power from an LED with periodic thickness variation (A) and an LED with uniform thickness (C).

FIG. 8A is a schematic of the laser diode (LD) structure where the LD is grown on sapphire.

FIG. 8B is a schematic of the laser diode (LD) structure where the LD is grown on n GaN or SiC.

### DETAILED DESCRIPTION OF THE INVENTION

A description of preferred embodiments of the invention follows.

In accordance with the invention, INₓGa₍₁₋ₓ₎N based multiquantum well (MQW) light emitting diodes (LEDs) and laser devices having high optical efficiency, are fabricated in which the efficiency is related to the Thickness Variation (TV) of the InₓGa₍₁₋ₓ₎N active layers. The thickness variation of active layers is found to be more important than the In composition fluctuation in quantum confinement (QC) of excitons (carriers) in these devices. In the invention, we have produced MQW InₓGa₍₁₋ₓ₎N layers with a periodic thickness variation, which results in periodic fluctuation of bandgap for the quantum confinement of carriers. Detailed STEM-Z contrast analysis (where image contrast is proportional to Z² (atomic number)²) was carried out to investigate the spatial distribution of In. We discovered that there is a longitudinal periodic variation in the thickness of InₓGa₍₁₋ₓ₎N layers with two periods, one short-range (SR-TV, 3 to 4 nm) and other long-range thickness variations of (LR-TV, 50 to 100 nm). It was also found that the effect of variation in In concentration is considerably less than the effect of thickness variation in the LED structures which exhibit high optical efficiency. A comparative microstructural study between high and low optical efficiency MQW structures indicates that thickness variation of InₓGa₍₁₋ₓ₎N active layers is the key to their enhancement in optical efficiency.

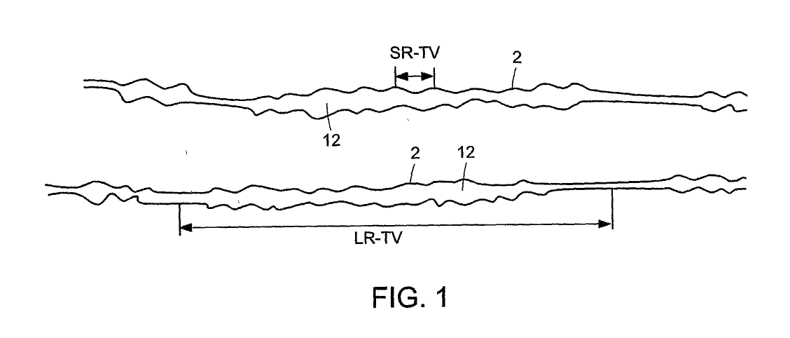

As shown in FIG. 1, QC regions 2 are formed within the boundaries of either LR-TV or SR-TV as a result of the thickness variations. The QC regions 2 trap the carriers, which recombine without being affected by the presence of stress induced dislocations. A detailed STEM-Z contrast analysis shows that the thickness variation of InₓGa₍₁₋ₓ₎N layers 12 is more important then the In composition fluctuation in producing quantum confined regions for carriers, leading to enhanced optical efficiency of LEDs and LDs. The bandgap change is dictated by the thickness:

(L_{z})via: ΔE₁=h²n²/(8m*L_{z}²) (1),

where E₁ is the lowest allowed energy level, h is Planck's constant, and m* is effective mass.

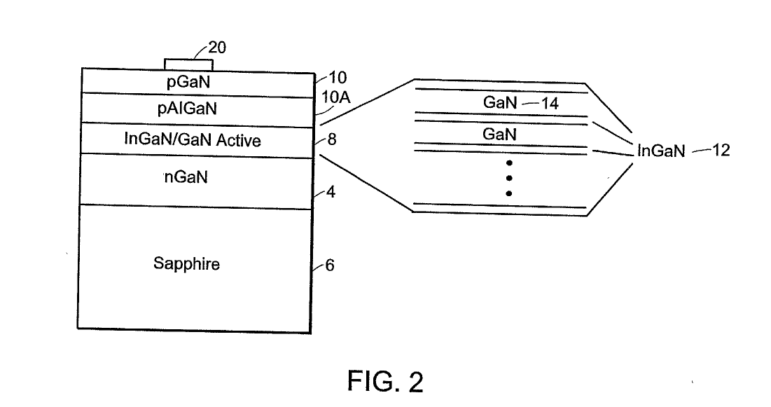

A schematic of an LED structure is set forth in FIG. 2. First, a Si-doped n-type GaN layer 4 (3-5 μm thick) is grown on a sapphire substrate 6 by means of metal-organic chemical vapor deposition (MOCVD). Then an InGaN(12)/GaN(14) MQW structure 8 is grown, on which Mg-doped p-type GaN layer 10 is grown. Optionally, Mg-doped p-type AlGaN layer 10A is grown between the MQW structure and p-type GaN.

We have analyzed the InGaN/GaN MQW structures using STEM-Z transmission electron microscopy (TEM), in which the image contrast is proportional to Z² (Z=atomic number). Since the atomic number of In (49) is much higher than that of Ga (31), the contrast due to In is enhanced by two and a half times compared to Ga, and the image contrast is dictated primarily by the In concentration.

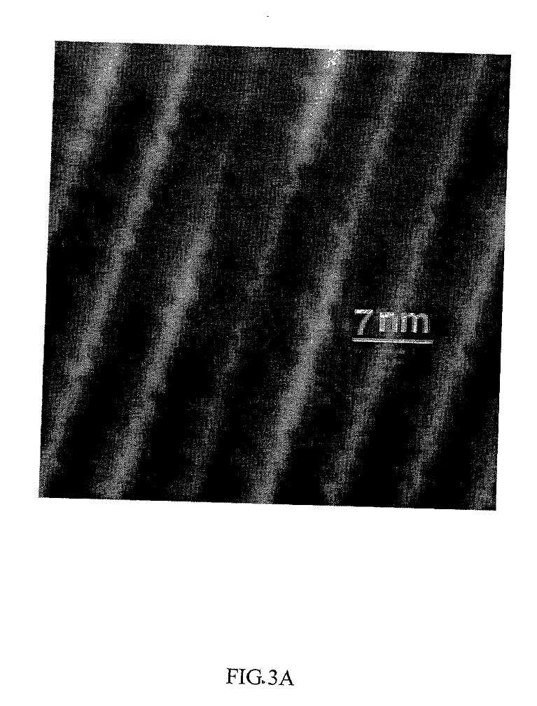

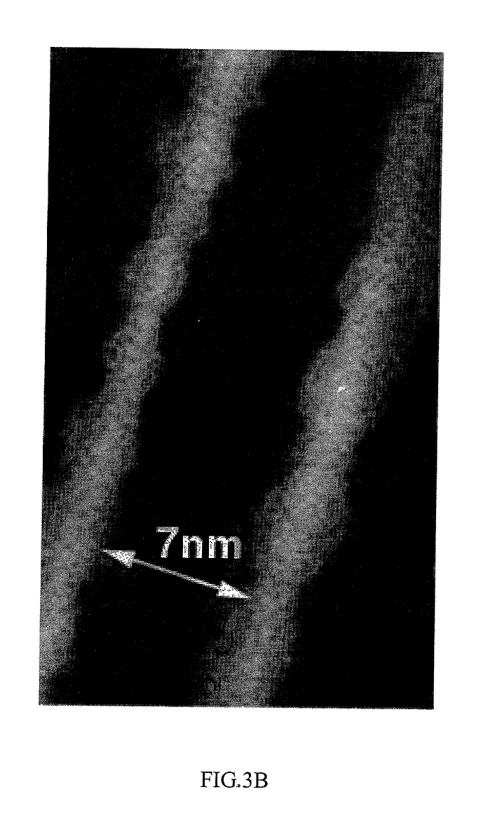

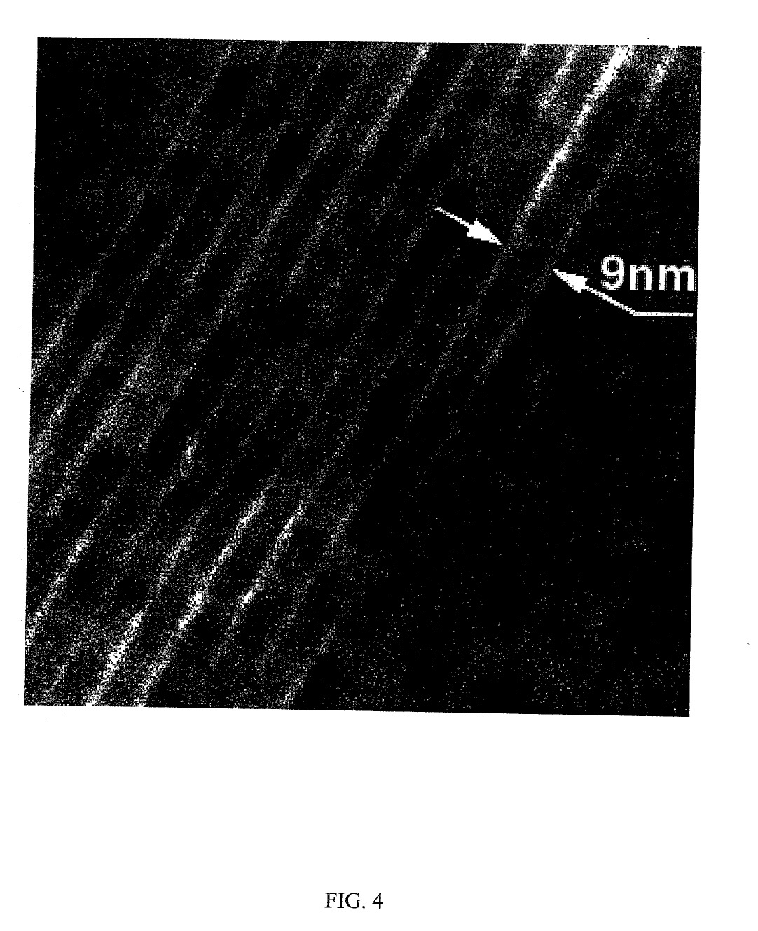

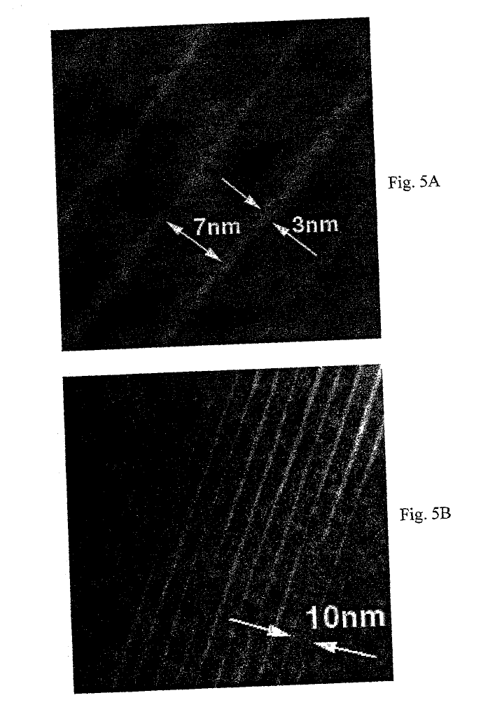

FIGS. 3-5 show STEM-Z contrast images in cross-section from two LED structures which exhibited high optical efficiencies. These specimens show short-range (3 to 4 nm period) and long-range (50 to 100 nm period) thickness variations in InGaN layers. This contrast analysis reveals that there are variations in In concentration, but they are not very large. In other embodiments, depending upon the growth of the structure, short-range thickness variations can range between 2 to 10 nm and long-range thickness variations can range between 50 and 200 nm.

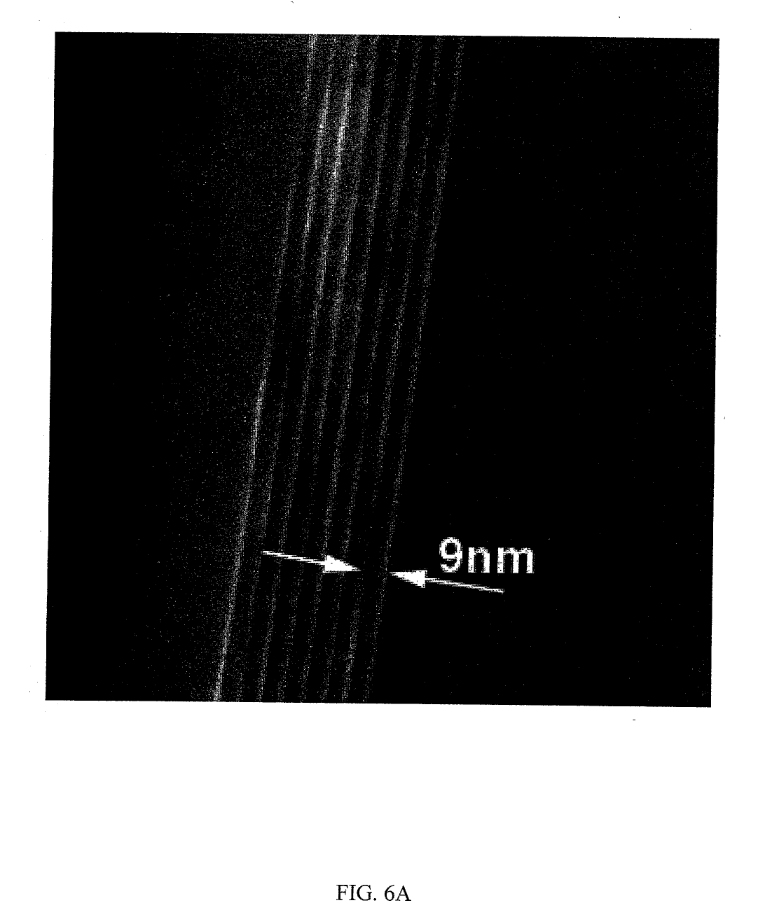

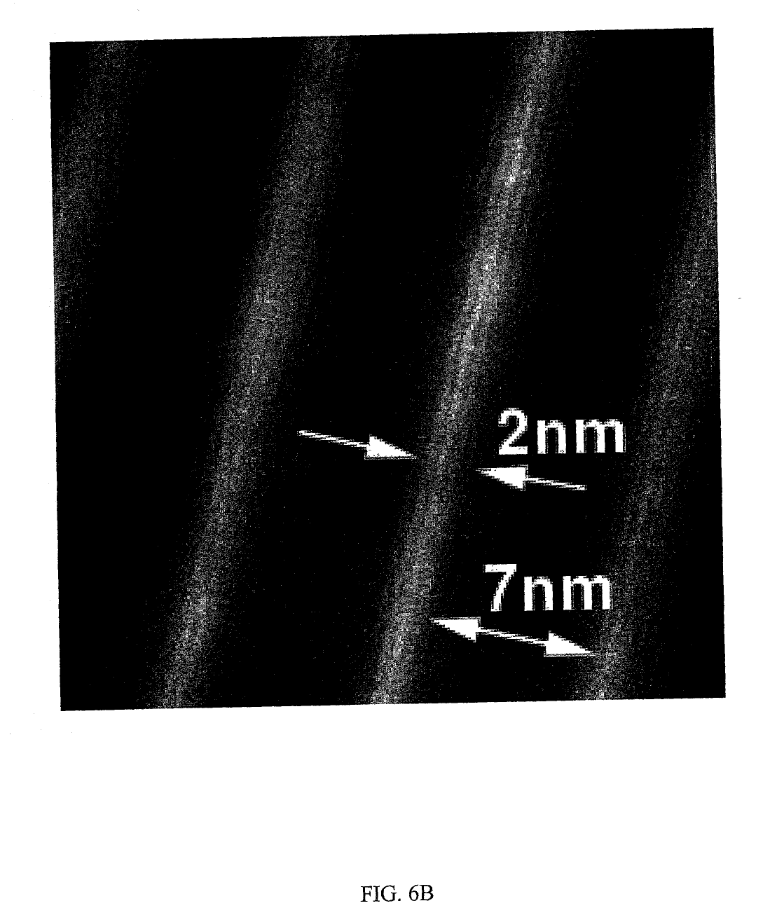

In contrast to the high optical efficiency specimens (FIGS. 3-5), a specimen with relatively low optical efficiencies is shown in FIGS. 6A and 6B. In these specimens, where optical efficiencies are lower by a factor of two to three than those for the specimens in FIGS. 3-5, the superlattice thickness as well as indium concentration is quite uniform.

The change in bandgap of InₓGa₍₁₋ₓ)N alloys can occur as function of the composition ‘x’ and the thickness ‘L_{z}’ of the superlattice. For a typical active layer composition (x=0.4), the change in bandgap is estimated to be as follows: x=0.4, bandgap=2.58 eV; x=0.5, bandgap=2.43 eV; x=0.3, bandgap=2.75 eV. This amounts to a +/−25% change (from x=0.4) in active layer composition. Experimentally observed composition fluctuations are less than +/−5%, which should lead to a less than 0.07 eV change in the bandgap. On the other hand, thickness variation from 3 to 2 nm can change the bandgap by more than 0.2 eV. Experimentally observed LR-TV is in the range of 20 to 50%, and SR-TV is less than 10%. Based on this analysis, we believe that the QC regions are defined principally by the thickness in InGaN layers.

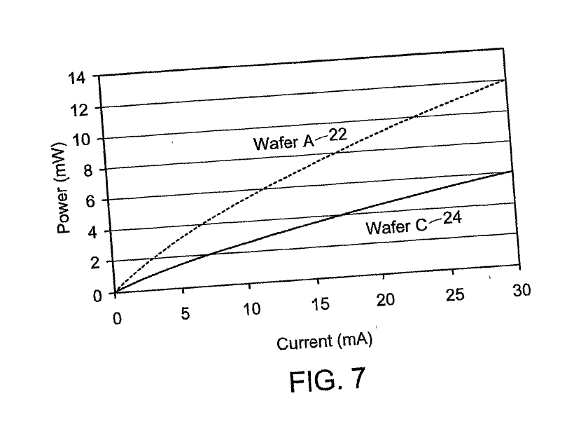

An LED is fabricated by forming an ohmic contact 20 on the top p-type GaN surface 10 of FIG. 2 and forming another contact on the n-type GaN surface 4 after it is exposed by etching the p-type GaN layer 10 and the active region 8. The light output power of LEDs from two such wafers is shown in FIG. 7. The output power of the LED from the specimen with InGaN thickness variation 22 is about a factor of 2-3 higher than that from the specimen with uniform InGaN thickness 24. Thus our experimental results on a comparative study of high- and low-efficiency LEDs demonstrate that thickness variation coupled with indium concentration variation is the key to enhancing the optical efficiencies in LEDs.

We believe that the thickness variation is caused by two-dimensional strain in the InₓGa₍₁₋ₓ₎N layer below its critical thickness. Since strain energy increases with thickness, the uniform thickness breaks into a periodic variation by which the free energy of the system can be lowered. Since the strain also increases with In concentration, some fluctuation in In concentration is also expected. This phenomenon of thickness variation has been well documented for pure germanium thin film growth on (100) silicon below its critical thickness where no composition fluctuation is involved references. We have modeled the thickness variation and derived the following relation for TV period (λ):

λ=πγ(1−ν)/[2(1+ν)²με²] (2),

where γ is the surface energy, ν is the Poisson's ratio, μ is the shear modulus of the film, and ε is the strain normal to the film surface. To avoid non-radiative recombination at the dislocations (density ρ), we derive the optimum structure to be:

ρ^{-1/2}>πγ(1−ν)/[2(1+ν)²με²] (3) or

ρ<{πγ(1−ν)/[2(1+ν)²με²]}⁻² (4).

We have estimated a typical value of λ using the following parameters for our growth conditions. For In_{0.4}Ga_{0.6}N, shear modulus is estimated to be 82 Gpa, Poisson's ratio to be 0.3, surface energy 4,000 ergs/cm², and strain 2%. These values result in λ of 80 nm, which is in good agreement with observed LR-TV. Since the period varies as ε⁻², the large misfit strain initially could lead to observed SR-TV.

Although we have shown the formation of QC regions 2 due to thickness variation in InGaN, a similar effect can be obtained in AlInGaN for shorter wavelength LEDs. In this case, superlattice can be formed between AlInGaN and AlGaN or between AlInGaN layers with different alloy compositions.

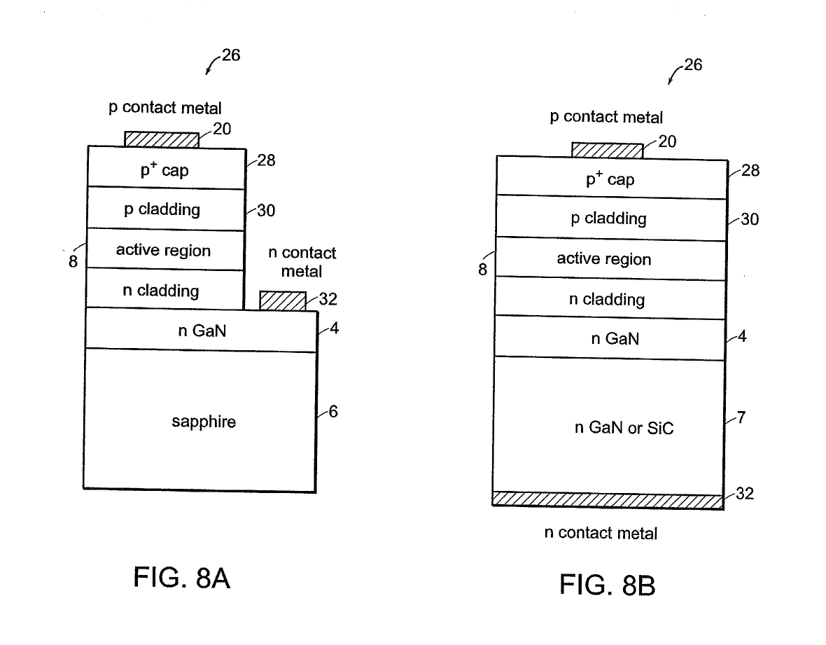

The QC regions 2 can also be beneficial for laser diode fabrication. FIGS. 8A and 8B show the schematic of a LD structure 26. In order to form the waveguide, either AlGaN, AlGaN/GaN superlattice, or AlInGaN layers can be used for the cladding layers, and InGaN/GaN or AlInGaN/AlGaN MQWs can be used for the active layers. To facilitate the ohmic contacts, a p-type GaN or InGaN cap layer 28 is added on top of the p-type cladding layer 30. If the LD structure 26 is grown on an insulating substrate 6 such as sapphire, the n contacts 32 are formed after the n-type GaN layer 4 is exposed by etching the top layers. If it is grown on top of a conducting substrate 7 such as SiC or GaN, the n contacts 32 are formed on the bottom of the substrate. The fabrication of the laser is completed by forming feedback mirrors. This can be done either by cleaving the wafer perpendicular to the contact stripe or by etching vertical walls using anisotropic etching techniques.

While this invention has been particularly shown and described with references to preferred embodiments thereof, it will be understood by those skilled in the art that various changes in form and details may be made therein without departing from the scope of the invention encompassed by the appended claims.

What is claimed is:

1. An optoelectronic device comprising:
a substrate; and
multiple quantum well (MQW) layers formed of Group III nitrides in which carriers recombine to emit photons, the layers being formed over the substrate and wherein the layers periodically vary in thickness along a length thereof.

2. The device of claim 1, wherein the layers have stress induced dislocations and the thickness variations result in the formation of quantum confinement regions which are smaller than separations between the stress induced dislocations.

3. The device of claim 2, wherein the quantum confinement regions trap the carriers, which recombine to produce the photons for efficient spontaneous emissions.

4. The device of claim 1, including contacts formed on the device and a voltage source coupled to the contacts to enable the device to operate as a high efficiency LED.

5. The device of claim 1, including a feedback mirror to produce coherent light.

6. The device of claim 1 in which the MQWs are formed of layers of InₓGa₍₁₋ₓ₎N and GaN.

7. The device of claim 1 in which the MQWs are formed of layers of Al_{y}InₓGa_{(1-x-y)}N and Al_{z}Ga_{(1-z)}N.

8. The device of claim 1 in which the substrate is formed of a compound from the class of Al₂O₃, Si, SiC, GaN or AlN or alloys thereof.

9. The device of claim 1 in which the thickness variation is a relatively short longitudinal range on the order of 2 to 10 nanometers (nm).

10. The device of claim 9 having an additional long-range thickness variation in the order of 50 to 200 nm and thickness variation more than 10%.

11. The device of claim 9 having an additional long-range thickness variation more than 10%.

12. The device of claim 9 having a long-range thickness variation period less than the separation of dislocations.

13. An LED comprising:
a substrate; and
multiple quantum well (MQW) layers formed of Group III nitrides in which carriers recombine to emit photons, the layers being formed over the substrate and wherein the layers periodically vary in thickness along a length thereof.

14. The device of claim 13, wherein the layers have stress induced dislocations and the thickness variations result in the formation of quantum confinement regions which are smaller than separations between the stress induced dislocations.

15. The device of claim 13, wherein the quantum confinement regions trap the carriers, which recombine to produce the photons for efficient spontaneous emission.

16. The LED of claim 13, wherein the substrate is formed of Al₂O₃, the quantum well layers are formed of InGaN/GaN, an n GaN is formed between the Al₂O₃ and quantum well layers, and a p GaN is formed over the quantum well layers.

17. A method of producing an optoelectronic device, comprising:
forming a substrate; and
forming multiple quantum well (MQW) layers over the substrate in which carriers recombine to emit photons, wherein the layers periodically vary in thickness along a length thereof, the layers forming P-N junctions of Group III nitrides.

18. The method as claimed in claim 17, wherein the layers have stress induced dislocations and the thickness variations result in the formation of quantum confinement regions which are smaller than separations between the stress and induced dislocations.

19. The method as claimed in claim 18, wherein the quantum confinement regions trap the carriers, which recombine to produce the photons to provide efficient spontaneous emissions.

20. The method as claimed in claim 17, further including:
forming contacts on the device; and
coupling a voltage source to the contacts to enable the device to operate as a high efficiency LED.

21. The method as claimed in claim 17, further including attaching mirrors at ends of the MQW to produce coherent light.

22. The method as claimed in claim 17, in which the MQWs are formed of layers of InₓGa₍₁₋ₓ₎N and GaN.

23. The method as claimed in claim 17, in which the MQWs are formed of layers of Al_{y}InₓGa_{(1-x-y)}N and Al_{z}Ga_{(1-z)}N.

24. The method as claimed in claim 17, in which the substrate is formed of a compound from the class of Al₂O₃, Si, SiC, GaN or AlN or alloys thereof.

25. The method as claimed in claim 17, in which the thickness variation is a relatively short longitudinal range on the order of 2 to 10 nanometers (nm).

26. The method as claimed in claim 25, having an additional long-range thickness variation in the order of 50 to 200 nm and thickness variation of more than 10%.

27. The method as claimed in claim 25, having an additional long-range thickness variation of more than 10%.

28. The method as claimed in claim 25, having a long-range thickness variation period less than the separation of dislocations.

29. A method of producing an LED comprising:
forming a substrate; and
forming multiple quantum well (MQW) layers formed of Group III nitrides over the substrate in which carriers recombine to emit photons, wherein the layers periodically vary in thickness along a length thereof.

30. The method as claimed in claim 29, wherein the layers have stress induced dislocations and the thickness variations result in the formation of quantum confinement regions which are smaller than separations between the stress induced dislocations.

31. The method as claimed in claim 30, wherein the quantum confinement regions trap the carriers which recombine to produce the photons to provide efficient spontaneous emissions.

32. A laser diode (LD) structure comprising:
an active region including InGaN/GaN or AlInGaN/AlGaN multiple quantum well (MQW) layers;
cladding layers;
a capping layer; and
ohmic contacts.

33. The structure of claim 32, wherein the cladding layer is comprised of either AlGaN, AlGaN/GaN superlattice or AlInGaN formed over the active layer.

34. The structure of claim 32, wherein the capping layer is comprised of either a GaN or a InGaN layer added to the top of the upper cladding layer.

35. A method of producing a laser diode (LD) structure comprising:
forming an active layer with either InGaN/GaN or AlInGaN/AlGaN multiple quantum well layers (MQW);
forming cladding layers with either AlGaN, AlGaN/GaN superlattice or AlInGaN above and below the active region;
forming a capping layer with either a GaN or a InGaN layer added to the top of the upper region of the cladding layer;
forming ohmic contacts with either a p-type GaN or a InGaN layer added to the top of the cladding layer; and
forming feedback mirror perpendicular to the contact stripe.
